(19) United States
(12) Patent Application Publication
(10) Pub. No.: US 2011/0318871 A1
(43) Pub. Date: Dec. 29, 2011

(54) PROCESS FOR PRODUCING PHOTOVOLTAIC DEVICE

(75) Inventors: Nobuki Yamashita, Tokyo (JP); Kengo Yamaguchi, Tokyo (JP); Tatsuji Horioka, Tokyo (JP)

(73) Assignee: MITSUBISHI HEAVY INDUSTRIES, LTD., Tokyo (JP)

(21) Appl. No.: 13/203,935

(22) PCT Filed: Feb. 25, 2010
(86) PCT No.: PCT/JP2010/052944

§ 371 Date: Aug. 30, 2011

(30) Foreign Application Priority Data
Jul. 10, 2009 (JP) 2009-164094

(51) Int. Cl. H01L 31/18

(52) U.S. Cl. 438/98; 257/E31.124

(57) ABSTRACT

There are provided a thermal barrier coating material and a thermal barrier coating member that can suppress spalling when used at a high temperature and have a high thermal barrier effect, a method for producing the same, a turbine member coated with a thermal barrier coating, and a gas turbine. The thermal barrier coating member comprises a heat resistant substrate, a bond coat layer formed thereon, and a ceramic layer formed further thereon, wherein the ceramic layer comprises an oxide which consists of an oxide represented by the general formula A₂Zr₂O₇ doped with a predetermined amount of CaO or MgO and has 10 volume % or more of a pyrochlore type crystal structure, where A represents any of La, Nd, Sm, Gd, and Dy.

### CROSS-REFERENCE TO RELATED APPLICATIONS

The present Application is the U.S. National Stage of International Application No. PCT/JP2010/052944, filed on Feb. 25, 2010, published in English; which Application claims priority benefit of Japanese Application No. 2009-164094, filed Jul. 10, 2009.

### TECHNICAL FIELD

The present invention relates to a process for producing a photovoltaic device. The invention relates particularly to a process for producing a photovoltaic device in which the electric power generation layer is formed by deposition.

### BACKGROUND ART

One known example of a photovoltaic device that receives light and converts the light into electric power is a thin-film solar cell comprising an electric power generation layer (a photovoltaic layer) formed by stacking thin films of silicon-based layers. A thin-film solar cell is generally produced by sequentially stacking, on top of a substrate, a transparent electrode layer (first transparent electrode layer), a silicon-based semiconductor layer (photovoltaic layer), and a back electrode layer comprising a backside transparent electrode layer (second transparent electrode layer) and a thin metal film.

The backside transparent electrode layer is composed mainly of a metal oxide such as zinc oxide (ZnO), tin oxide (SnO₂) or indium tin oxide (ITO). In order to lower the resistance of the backside transparent electrode layer, gallium oxide or aluminum oxide, and fluorine and the like are added to the above-mentioned metal oxide. However, because the backside transparent electrode layer still exhibits a high resistance compared with a metal electrode, the electric current generated in the photovoltaic layer suffers power loss while flowing through the backside transparent electrode layer. Accordingly, in order to maximize the electric power that can be accessed externally, an integrated structure that reduces power loss is known. An integrated structure is a structure in which a plurality of electric power generation units are formed on a single substrate, and these units are connected together in series. Isolation trenches and connection slots are formed in a direction perpendicular to the series connection direction using laser scribing.

In order to improve the electric power generation performance of an integrated solar cell, increasing the reflectance of the thin metal film and reducing the resistance of the back electrode layer are important factors. Consequently, Ag thin films, which exhibit high reflectance across a broad range of wavelengths, have generally been used as the thin metal films within thin-film silicon-based solar cells and thin-film silicon-based tandem solar cells. PTL 1 discloses a photovoltaic device that includes a back electrode layer comprising a thin film of Ag.

### CITATION LIST

### Patent Literature

{PTL 1} Japanese Examined Patent Application, Publication No. Hei 5-18275 (page 1, column 1, line 22 to page 1, column 2, line 7)

### SUMMARY OF INVENTION

### Technical Problem

However, Ag has a high degree of toughness, and therefore is prone to burr generation during laser etching of the back electrode layer. As a result, the laser etching conditions must be optimized and controlled in a stable manner. However, the optimal range for the laser processing conditions for Ag thin films is very narrow, and the robustness tends to be poor, meaning control of the conditions is problematic. PTL 1 also discloses the use of a Cu thin film instead of the Ag thin film for the back electrode layer. Cu has a lower degree of toughness than Ag. Accordingly, the optimal range for the laser processing conditions is broader than that of Ag thin films, and superior robustness can be achieved relative to fluctuations in the laser power or the like. As a result, in the case of a back electrode layer comprising a Cu thin film, the laser etching conditions can be optimized and controlled in a stable manner with comparative ease, meaning a suppression of burr generation during laser processing can be expected. On the other hand, Cu oxidizes more readily than Ag, meaning the physical properties of the prepared Cu thin film tend to vary depending on the deposition conditions and the element structure (the stacking configuration). As a result, even if the Ag thin film deposition conditions disclosed in PTL 1 are applied to the deposition of a Cu thin film, a photovoltaic conversion efficiency equivalent to that of a photovoltaic device including a back electrode layer comprising an Ag thin film cannot be achieved.

The present invention has been developed in light of the circumstances described above, and provides a process for producing a photovoltaic device that offers easy laser etching and high electric power generation efficiency.

### Solution to Problem

The inventors of the present invention focused their attention on the above-mentioned advantages offered by the physical properties of Cu, and undertook intensive investigation into developing a process for producing a photovoltaic device that exhibited high electric power generation efficiency even when a Cu thin film was used in the back electrode layer. Cu exhibits high light reflectance, but oxidizes readily, and the light reflectance deteriorates upon oxidation. Further, when applied to use within a photovoltaic device, the Cu is deposited on a backside transparent electrode layer comprising mainly a metal oxide, which provides conditions that further promote oxidation. Furthermore, solar cells tend to be installed outdoors where they are exposed to the natural environment, and therefore require good weather resistance. Accordingly, in order to develop a photovoltaic device having high electric power generation efficiency, it is important that oxidation of the Cu is suppressed during formation of the Cu thin film, and that oxidation caused by deterioration over time is also suppressed, enabling the high light reflectance of the Cu thin film to be maintained.

In order to address the issues outlined above, the present invention provides a process for producing a photovoltaic device that includes forming two photovoltaic layers and a back electrode layer on a substrate, wherein formation of the back electrode layer comprises a backside transparent electrode layer formation step and a Cu thin film formation step, the Cu thin film formation step comprises, in sequence, an evacuation step and a deposition step, the ultimate pressure reached in the evacuation step is not more than 2×10⁻⁴ Pa, and the temperature in the deposition step is not less than 120° C. and not more than 240° C.

In the photovoltaic device having two photovoltaic layers (a so-called tandem solar cell) according to the present invention, the absorption band for the photovoltaic layer nearest the back electrode layer comprises wavelengths of 650 nm or greater. Accordingly, the back electrode layer requires a high level of reflectance for wavelengths of 650 nm or greater.

The ultimate pressure reached in the evacuation step of the Cu thin film formation step is preferably not more than 2×10⁻⁴ Pa. As a result, the moisture and oxygen contained within the atmosphere can be reduced to a concentration not more than a predetermined limit (500 ppm). Accordingly, oxidation of the Cu thin film can be suppressed, ensuring a high level of light reflectance is obtained.

The temperature in the deposition step is preferably not less than 120° C. and not more than 240° C. By ensuring that the deposition temperature is not less than 120° C., a high level of light reflectance is achieved for the Cu thin film. Accordingly, the short-circuit current of the back electrode layer can be increased, enabling an improvement in the module output. On the other hand, if the deposition temperature exceeds 240° C., then the doping materials within the amorphous silicon p-layer and n-layer that constitute the photovoltaic layer tend to diffuse into the i-layer. This causes a reduction in the open-circuit voltage and a decrease in the module output. The module output is particularly favorable for deposition temperatures of not less than 150° C. and not more than 200° C. If the deposition temperature is less than 120° C., then atom migration during deposition of the Cu is suppressed, which leads to the generation of large numbers of voids and defects at the crystal grain boundaries within the Cu thin film at the interface with the backside transparent electrode layer, resulting in a decrease in the reflectance, a reduction in the short-circuit current, and a decrease in the module output.

The above-mentioned deposition step includes an initial stage of applying an initial target supplied electric power density, and a steady-state stage of maintaining a steady-state target supplied electric power density, wherein the initial target supplied electric power density is preferably not less than 10% and not more than 50% of the steady-state target supplied electric power density.

The Cu thin film is deposited by sputtering on top of the backside transparent electrode layer comprising mainly a metal oxide. When deposition is performed by sputtering, the sputtered particles of Cu adhered to the substrate have a high level of energy. As a result, the Cu reacts with the oxygen of the metal oxide that represents the main component of the backside transparent electrode layer, forming a black or red-brown Cu oxide, and therefore the backside transparent electrode layer suffers damage. As this oxidized interface layer becomes thicker (namely, as the damage increases), the light reflectance of the back electrode layer decreases significantly, leading to a decrease in the module output. In order to avoid this problem, it is necessary to reduce the initial deposition rate of the Cu thin film, thereby lowering the energy of the sputtered particles and suppressing the Cu oxidation that leads to damage of the interface.

From the viewpoint of oxidation suppression, the initial target supplied electric power density is preferably as low as possible. Further, in consideration of potential damage to the interface between the backside transparent electrode layer and the Cu thin film, the initial target supplied electric power density is preferably not more than 50% of the steady-state target supplied electric power density. However, if the initial target supplied electric power density is less than 10% of the steady-state target supplied electric power density, then the deposition rate becomes overly slow, and impurity gases within the atmosphere tend to be incorporated within the film, resulting in lower reflectance for the Cu thin film.

The time for which the initial target supplied electric power density is applied is preferably not less than 10% and not more than 30% of the total deposition time.

If the time for which the initial target supplied electric power density is applied exceeds 30% of the total deposition time, then the takt time lengthens, resulting in a decrease in productivity. In contrast, if the time is less than 10%, then the initial target supplied electric power density must be increased, which increases the damage at the above-mentioned interface and causes a decrease in the reflectance.

The above-mentioned deposition step preferably includes a transition stage for transitioning from the initial target supplied electric power density to the steady-state target supplied electric power density, wherein the transition time for the transition stage is not less than 5% and not more than 10% of the total deposition time.

If the time for the transition stage is shorter than 5% of the total deposition time required for depositing the Cu thin film, then deposition at the steady-state target supplied electric power density, which causes damage to the above-mentioned interface, starts before Cu deposition in the state that causes minimal damage to the interface finishes, meaning oxidation tends to proceed. On the other hand, if the time exceeds 10%, then because it becomes difficult to achieve the designed film thickness, maintaining a uniform takt time becomes impossible.

The back electrode layer may comprise a protective film on the Cu thin film. The step of forming the protective film may be included within the Cu thin film formation step, in which case the protective film may be stacked on top of the Cu thin film without exposure to the atmosphere. The protective film is used for protecting the Cu thin film by preventing contact with moisture and oxygen and the like within the atmosphere. By stacking this protective film on the Cu thin film, the corrosion resistance of the Cu thin film can be improved.

### ADVANTAGEOUS EFFECTS OF INVENTION

The present invention enables the production of a photovoltaic device that offers easy laser processing and high electric power generation efficiency.

### BRIEF DESCRIPTION OF DRAWINGS

FIG. 1 A schematic representation illustrating the structure of a photovoltaic device produced using a process for producing a photovoltaic device according to the present invention.

FIG. 2 A schematic illustration describing one embodiment for producing a solar cell panel.

FIG. 3 A schematic illustration describing one embodiment for producing a solar cell panel.

FIG. 4 A schematic illustration describing one embodiment for producing a solar cell panel.

FIG. 5 A schematic illustration describing one embodiment for producing a solar cell panel.

FIG. 6 A graph illustrating the wavelength dispersion of the light reflectance of a thin film upon variation in the ultimate pressure within the evacuation step, wherein (a) illustrates cases in which a Cu thin film was used, and (b) illustrates cases in which an Ag thin film was used.

FIG. 7 A graph illustrating the wavelength dispersion of the light reflectance upon variation in the deposition temperature during deposition of a Cu thin film.

FIG. 8 A graph illustrating the relationship between the deposition temperature and the short-circuit current for a tandem solar cell module according to an embodiment of the present invention.

FIG. 9 A graph illustrating the relationship between the deposition temperature and the open-circuit voltage for a tandem solar cell module according to an embodiment of the present invention.

FIG. 10 A graph illustrating the relationship between the deposition temperature and the form factor for a tandem solar cell module according to an embodiment of the present invention.

FIG. 11 A graph illustrating the relationship between the deposition temperature and the module output for a tandem solar cell module according to an embodiment of the present invention.

FIG. 12 A graph illustrating control profiles for the target supplied electric power density during Cu thin film deposition.

FIG. 13 A graph illustrating the wavelength dispersion of the reflectance for different target supplied electric power density control profiles during deposition of a metal thin film, wherein (a) illustrates cases in which a Cu thin film was used, and (b) illustrates cases in which an Ag thin film was used.

FIG. 14 A graph illustrating the wavelength dispersion of the light reflectance upon variation in the Cu thin film thickness.

FIG. 15 A graph illustrating the relationship between the Cu thin film thickness and the short-circuit current for a tandem solar cell module according to an embodiment of the present invention.

FIG. 16 A graph illustrating the relationship between the Cu thin film thickness and the open-circuit voltage for a tandem solar cell module according to an embodiment of the present invention.

FIG. 17 A graph illustrating the relationship between the Cu thin film thickness and the form factor for a tandem solar cell module according to an embodiment of the present invention.

FIG. 18 A graph illustrating the relationship between the Cu thin film thickness and the module output for a tandem solar cell module according to an embodiment of the present invention.

FIG. 19 A graph illustrating the wavelength dispersion of the light reflectance of a Cu thin film/Ti film structure upon variation in the Ti film thickness.

### DESCRIPTION OF EMBODIMENTS

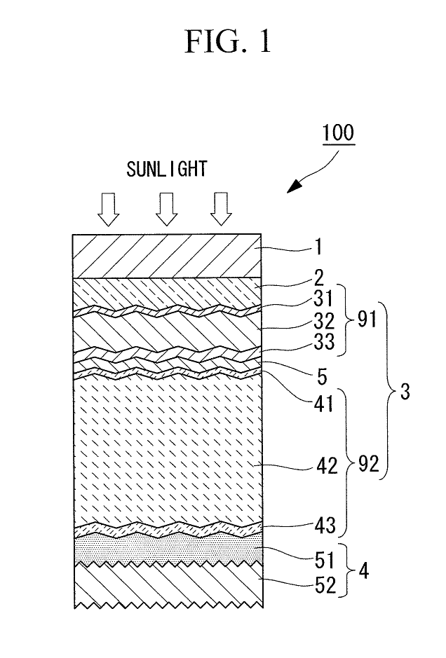

FIG. 1 is a schematic representation illustrating the structure of a photovoltaic device produced using a process for producing a photovoltaic device according to the present invention. A photovoltaic device 100 is a tandem silicon-based solar cell, and comprises a substrate 1, a transparent electrode layer 2, a first cell layer 91 (amorphous silicon-based) and a second cell layer 92 (crystalline silicon-based) as a photovoltaic layer 3, an intermediate contact layer 5, and a back electrode layer 4. Here, the term “silicon-based” is a generic term that includes silicon (Si), silicon carbide (SiC) and silicon germanium (Site). Further, the term “crystalline silicon-based” describes a silicon system other than an amorphous silicon system, and includes both microcrystalline silicon systems and polycrystalline silicon systems.

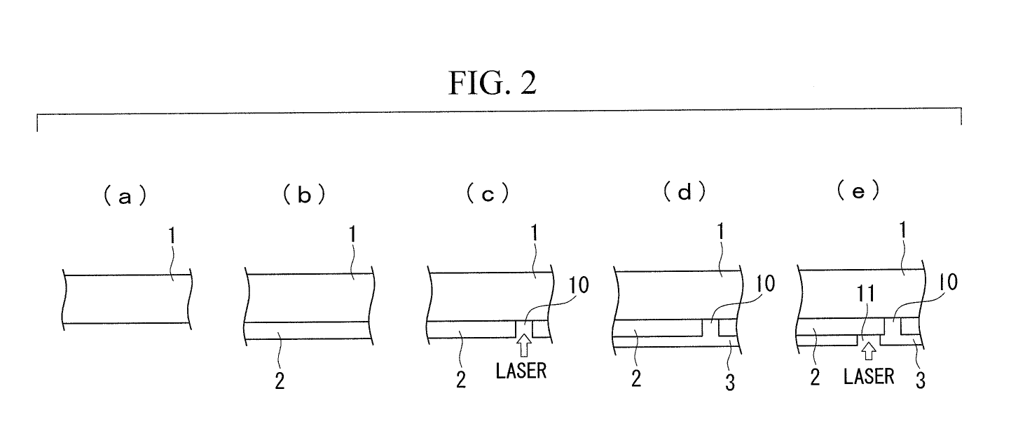

The process for producing a photovoltaic device according to an embodiment of the present invention is described below, using the production steps for a solar cell panel as an example. FIG. 2 to FIG. 5 are schematic representations illustrating the process for producing a solar cell panel according to this embodiment.

(1) FIG. 2(a)

A soda float glass substrate (for example with dimensions of 1.4 m×1.1 m×thickness: 3.5 to 4.5 mm) is used as the substrate 1. The edges of the substrate are preferably subjected to corner chamfering or R-face chamfering to prevent damage caused by thermal stress or impacts or the like.

(2) FIG. 2(b)

A transparent electrode film comprising mainly tin oxide (SnO₂) and having a film thickness of approximately not less than 500 nm and not more than 800 nm is deposited as the transparent electrode layer 2 using a thermal CVD apparatus at a temperature of approximately 500° C. During this deposition, a texture comprising suitable asperity is formed on the surface of the transparent electrode film. In addition to the transparent electrode film, the transparent electrode layer 2 may also include an alkali barrier film (not shown in the figure) formed between the substrate 1 and the transparent electrode film. The alkali barrier film is formed using a thermal CVD apparatus at a temperature of approximately 500° C. to deposit a silicon oxide film (SiO₂) having a film thickness of 50 nm to 150 nm.

(3) FIG. 2(c)

Subsequently, the substrate 1 is mounted on an X-Y table, and the first harmonic of a YAG laser (1064 nm) is irradiated onto the surface of the transparent electrode film, as shown by the arrow in the figure. The laser power is adjusted to ensure an appropriate process speed, and the transparent electrode film is then moved in a direction perpendicular to the direction of the series connection of the electric power generation cells, thereby causing a relative movement between the substrate 1 and the laser light, and conducting laser etching across a strip having a predetermined width of approximately 6 mm to 15 mm to form a slot 10.

(4) FIG. 2(d)

Using a plasma-enhanced CVD apparatus, a p-layer, an i-layer and an n-layer, each composed of a thin film of amorphous silicon, are deposited as the first cell layer 91. Using SiH₄ gas and H₂ gas as the main raw materials, and under conditions including a reduced pressure atmosphere of not less than 30 Pa and not more than 1,000 Pa and a substrate temperature of approximately 200° C., an amorphous silicon p-layer 31, an amorphous silicon i-layer 32 and an amorphous silicon n-layer 33 are deposited, in that order, on the transparent electrode layer 2, with the p-layer 31 closest to the surface from which incident sunlight enters. The amorphous silicon p-layer 31 comprises mainly amorphous B-doped silicon, and has a thickness of not less than 10 nm and not more than 30 nm. The amorphous silicon i-layer 32 has a thickness of not less than 200 nm and not more than 350 nm. The amorphous silicon n-layer 33 comprises mainly P-doped silicon in which microcrystalline silicon is incorporated within amorphous silicon, and has a thickness of not less than 30 nm and not more than 50 nm. A buffer layer may be provided between the amorphous silicon p-layer 31 and the amorphous silicon i-layer 32 in order to improve the interface properties.

Next, using a plasma-enhanced CVD apparatus under conditions including a reduced pressure atmosphere of not more than 3,000 Pa, a substrate temperature of approximately 200° C. and a plasma generation frequency of not less than 40 MHz and not more than 100 MHz, a crystalline silicon p-layer 41, a crystalline silicon i-layer 42 and a crystalline silicon n-layer 43 are deposited, in that order, as the second cell layer 92 on top of the first cell layer 91. The crystalline silicon p-layer 41 comprises mainly B-doped microcrystalline silicon, and has a thickness of not less than 10 nm and not more than 50 nm. The crystalline silicon i-layer 42 comprises mainly microcrystalline silicon, and has a thickness of not less than 1.2 μm and not more than 3.0 μm. The crystalline silicon n-layer 43 comprises mainly P-doped microcrystalline silicon, and has a thickness of not less than 20 nm and not more than 50 nm.

During formation of the i-layer film comprising mainly microcrystalline silicon using a plasma-enhanced CVD method, a distance d between the plasma discharge electrode and the surface of the substrate 1 is preferably not less than 3 mm and not more than 10 mm. If this distance d is less than 3 mm, then the precision of the various structural components within the film deposition chamber required for processing large substrates means that maintaining the distance d at a constant value becomes difficult, which increases the possibility of the electrode getting too close and making the discharge unstable. If the distance d exceeds 10 mm, then achieving a satisfactory deposition rate (of at least 1 nm/s) becomes difficult, and the uniformity of the plasma also deteriorates, causing a deterioration in the quality of the film due to ion impact.

An intermediate contact layer 5 that functions as a semi-reflective film for improving the contact properties and achieving electrical current consistency may be provided between the first cell layer 91 and the second cell layer 92. For example, a GZO (Ga-doped ZnO) film with a film thickness of not less than 20 nm and not more than 100 nm may be deposited as the intermediate contact layer 5 using a sputtering apparatus with a Ga-doped ZnO sintered body as the target. Further, in some cases the contact layer 5 need not be provided.

(5) FIG. 2(e)

The substrate 1 is mounted on an X-Y table, and the second harmonic of a laser diode excited YAG laser (532 nm) is irradiated onto the surface of the photovoltaic layer 3, as shown by the arrow in the figure. With the pulse oscillation set to 10 kHz to 20 kHz, the laser power is adjusted so as to achieve a suitable process speed, and laser etching is conducted at a point approximately 100 μm to 150 μm to the side of the laser etching line within the transparent electrode layer 2, so as to form a connection slot 11. The laser may also be irradiated from the side of the substrate 1, and in this case, because the high vapor pressure generated by the energy absorbed by the amorphous silicon-based first cell layer 91 of the photovoltaic layer 3 can be utilized in etching the photovoltaic layer 3, more stable laser etching processing can be performed. The position of the laser etching line is determined with due consideration of positioning tolerances, so as not to overlap with the previously formed etching line.

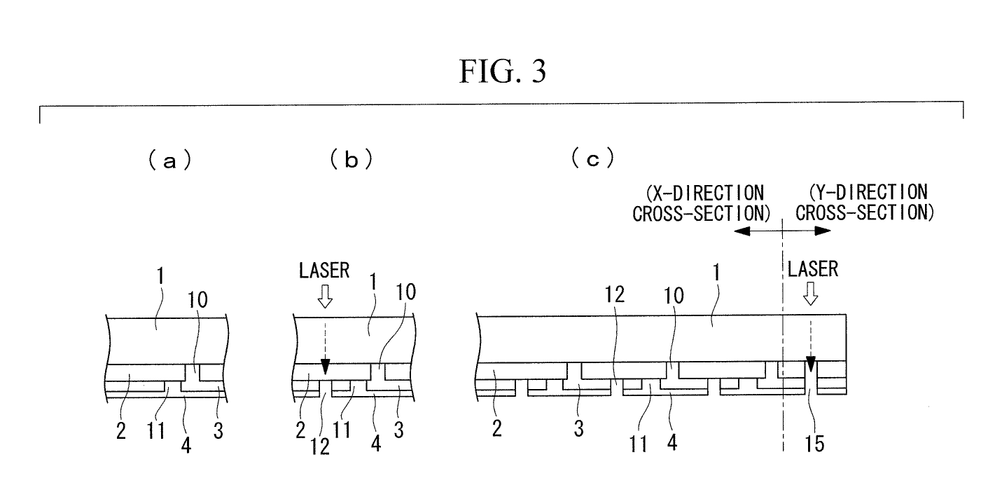

(6) FIG. 3(a)

In this embodiment, the back electrode layer 4 comprises a backside transparent electrode layer 51 and a Cu thin film 52, with the backside transparent electrode layer 51 positioned nearer the substrate 1. The step of forming this back electrode layer 4 comprises a backside transparent electrode layer formation step and a Cu thin film formation step. Both of these steps are performed using a sputtering method.

In the step of forming the backside transparent electrode layer, the backside transparent electrode layer 51 is deposited using a sputtering apparatus. The backside transparent electrode layer 51 is provided for the purposes of reducing the contact resistance between the photovoltaic layer 3 and the Cu thin film 52, and improving the light reflection. The backside transparent electrode layer 51 is a transparent conductive film comprising mainly a metal oxide, and may be, for example, a GZO (Ga-doped ZnO) film with a thickness of not less than 50 nm and not more than 100 nm.

The Cu thin film formation step comprises an evacuation step in which the inside of the chamber is evacuated to generate a vacuum prior to deposition of the Cu thin film 52, and a deposition step in which electric power is applied to effect deposition. In order to suppress oxidation of the Cu thin film 52 by moisture and oxygen within the atmosphere, the ultimate pressure reached in the evacuation step of the Cu thin film formation step is set to not more than 2×10⁻⁴ Pa, and Ar gas is then introduced into the chamber so that the partial pressure ratio with the ultimate pressure (ultimate pressure/Ar gas) is a value not more than of 5×10⁻⁴. The temperature during the deposition step is set to not less than 120° C. and not more than 240° C., and the Cu thin film is deposited with a thickness of not less than 100 nm and not more than 450 nm.

The control profile for the target supplied electric power density during the deposition step includes an initial stage of applying an initial target supplied electric power density, a transition stage of transitioning from the initial target supplied electric power density to a steady-state target supplied electric power density, and a steady-state stage of maintaining the steady-state target supplied electric power density. The total deposition time for depositing the Cu film in the deposition step is determined by the takt. This determines the deposition rate required for achieving the targeted film thickness. This deposition rate exhibits a proportional relationship with the target supplied electric power density, and therefore the target supplied electric power density is determined in accordance with the targeted deposition rate. In those cases where the target supplied electric power density is controlled, because the initial target power is set to a lower value than the case in which the electric power density is not controlled, the deposition rate also decreases. This factor is taken into consideration when determining the steady-state target supplied electric power density.

The initial target supplied electric power density is set to a value of not less than 10% and not more than 50% of the steady-state target supplied electric power density, and is applied for a period of time that is not less than 10% and not more than 30% of the total deposition time. In the transition stage, the electric power density is altered from the initial target supplied electric power density to the steady-state target supplied electric power density over a time period that is not less than 5% and not more than 10% of the total deposition time. If the initial target supplied electric power density is greater than 50% of the steady-state target supplied electric power density, then damage to the interface between the backside transparent electrode layer 51 and the Cu thin film 52 tends to increase, and a high reflectance may not be achievable. If the time for which the initial target supplied electric power density is applied exceeds 30% of the total deposition time, or the time for which the target supplied electric power density is applied during the transition stage exceeds 10% of the total deposition time, then maintaining the takt time becomes difficult.

In the Cu thin film formation step, a protective film may be formed on the Cu thin film 52 within the same chamber, without exposing the Cu thin film to the atmosphere. In this embodiment, Ti is used as the protective film, which exhibits a superior anticorrosive effect for Cu. The thickness of the protective film is not less than 5 nm and not more than 150 nm. Examples of other films that exhibit a superior anticorrosive effect include metal oxide films such as Cr—O, but being oxides, deposition of such films within the same chamber releases oxygen into the atmosphere, which can cause oxidation of the Cu thin film. Further, using a separate chamber increases the cost. Examples of metal films that may be used include Cr, Ti and Al. Of these, Ti forms a dense surface passivation film of TiO₂, and therefore offers the most powerful anticorrosive effect. Cr and Al may alloy with the Cu, causing a deterioration in the reflection properties. If the thickness of the protective film is less than 5 nm, then the desired anticorrosive effect may be unobtainable, whereas if the thickness exceeds 150 nm, then detachment due to stress becomes more likely.

(7) FIG. 3(b)

The substrate 1 is mounted on an X-Y table, and the second harmonic of a laser diode-excited YAG laser (532 nm) is irradiated through the substrate 1, as shown by the arrow in the figure. The laser light is absorbed by the photovoltaic layer 3, and by utilizing the high gas vapor pressure generated at this point, the back electrode layer 4 is removed by explosive fracture. With the pulse oscillation set to not less than 1 kHz and not more than 100 kHz, the laser power is adjusted so as to achieve a suitable process speed, and laser etching is conducted at a point approximately 250 μm to 400 μm to the side of the laser etching line within the transparent electrode layer 2, so as to form a slot 12.

(8) FIG. 3(c) and FIG. 4(a)

The electric power generation region is then compartmentalized, by using laser etching to remove the effect wherein the serially connected portions at the film edges near the edges of the substrate are prone to short circuits. The substrate 1 is mounted on an X-Y table, and the second harmonic of a laser diode-excited YAG laser (532 nm) is irradiated through the substrate 1. The laser light is absorbed by the transparent electrode layer 2 and the photovoltaic layer 3, and by utilizing the high gas vapor pressure generated at this point, the back electrode layer 4 is removed by explosive fracture, and the back electrode layer 4, the photovoltaic layer 3 and the transparent electrode layer 2 are removed. With the pulse oscillation set to not less than 1 kHz and not more than 100 kHz, the laser power is adjusted so as to achieve a suitable process speed, and laser etching is conducted at a point approximately 5 mm to 20 mm from the edge of the substrate 1, so as to form an X-direction insulation slot 15 as illustrated in FIG. 3(c). FIG. 3(c) represents an X-direction cross-sectional view cut along the direction of the series connection of the photovoltaic layer 3, and therefore the location in the figure where the insulation slot 15 is formed should actually appear as a peripheral film removed region 14 in which the back electrode layer 4, the photovoltaic layer 3 and the transparent electrode layer 2 have been removed by film polishing (see FIG. 4(a)), but in order to facilitate description of the processing of the edges of the substrate 1, this location in the figure represents a Y-direction cross-sectional view, so that the formed insulation slot represents an X-direction insulation slot 15. A Y-direction insulation slot need not be provided at this point, because a film surface polishing and removal treatment is conducted on the peripheral film removal regions of the substrate 1 in a later step.

Completing the etching of the insulation slot 15 at a position 5 mm to 15 mm from the edge of the substrate 1 is preferred, as it ensures that the insulation slot 15 is effective in inhibiting external moisture from entering the interior of the solar cell module 6 via the edges of the solar cell panel.

Although the laser light used in the steps until this point has been specified as YAG laser light, light from a YVO4 laser or fiber laser or the like may also be used in a similar manner.

(9) FIG. 4 (a: View from Solar Cell Film Surface Side, b: View from Substrate Side of Light Incident Surface)

In order to ensure favorable adhesion and sealing of a backing sheet 24 via EVA or the like in a subsequent step, the stacked films around the periphery of the substrate 1 (in a peripheral film removal region 14), which tend to be uneven and prone to peeling, are removed to form a peripheral film removed region 14. During removal of the films from a region that is 5 mm to 20 mm from the edge around the entire periphery of the substrate 1, grinding or blast polishing or the like is used to remove the back electrode layer 4, the photovoltaic layer 3 and the transparent electrode layer 2 from a region that is closer to the substrate edge in the X direction than the insulation slot 15 provided in the above step of FIG. 3(c), and closer to the substrate edge in the Y direction than the slot 10 provided near the substrate edge.

Grinding debris or abrasive grains are removed by washing the substrate 1.

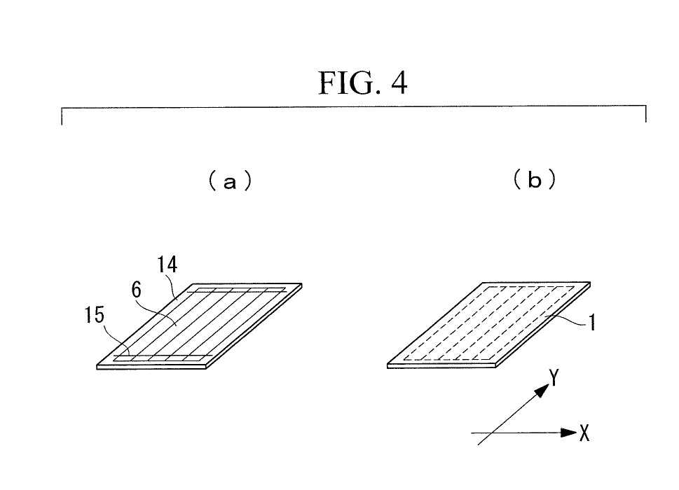

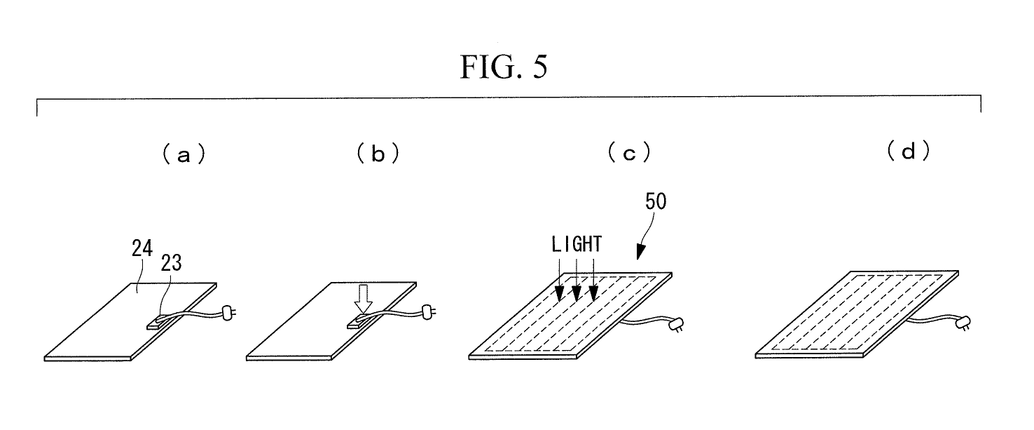

### (10) FIG. 5

An attachment portion for a terminal box 23 is prepared by providing an open through-window in the backing sheet 24 to expose a collecting plate. A plurality of layers of an insulating material are provided in this open through-window portion in order to prevent external moisture and the like entering the solar cell module.

Processing is conducted so as to enable current collection, using a Cu foil, from the series-connected solar cell electric power generation cell at one end and the solar cell electric power generation cell at the other end, in order to enable electric power to be extracted from the terminal box 23 on the rear surface of the solar cell panel. In order to prevent short circuits between the Cu foil and the various portions, an insulating sheet that is wider than the width of the Cu foil is provided.

Following arrangement of the collecting Cu foil and the like at predetermined positions, the entire solar cell module 6 is covered with a sheet of an adhesive filling material such as EVA (ethylene-vinyl acetate copolymer), which is arranged so as not to protrude beyond the substrate 1.

A backing sheet 24 with a superior waterproofing effect is then positioned on top of the EVA. In this embodiment, in order to achieve a superior waterproofing and moisture-proofing effect, the backing sheet 24 is formed as a three-layer structure comprising a PET sheet, an Al foil and a PET sheet.

The structure comprising the components up to and including the backing sheet 24 arranged in predetermined positions is subjected to internal degassing under a reduced pressure atmosphere and pressing at approximately 150° C. to 160° C. using a laminator, thereby causing cross-linking of the EVA that tightly seals the structure.

(11) FIG. 5(a)

The terminal box 23 is attached to the back of the solar cell module 6 using an adhesive.

(12) FIG. 5(b)

The Cu foil and an output cable from the terminal box 23 are connected using solder or the like, and the interior of the terminal box 23 is filled and sealed with a sealant (a potting material). This completes the production of the solar cell panel 50.

(13) FIG. 5(c)

The solar cell panel 50 formed via the steps up to and including FIG. 5(b) is then subjected to an electric power generation test, as well as other tests for evaluating specific performance factors. The electric power generation test is conducted using a solar simulator that emits a standard sunlight of AM 1.5 (1,000 W/m²).

(14) FIG. 5(d)

In tandem with the electric power generation test (FIG. 5(c)), a variety of specific performance factors including the external appearance are evaluated.

The grounds for determining the formation conditions for the above-mentioned back electrode layer are described below.

### (Ultimate Pressure of Evacuation Step)

Cu thin films and Ag thin films were deposited on glass substrates under various ultimate pressure values in the evacuation step, thus preparing a series of test pieces. The deposition was performed using a sputtering apparatus. The ultimate pressure for the evacuation step was set to 1×10⁻³ Pa, 2×10⁻⁴ Pa or 5×10⁻⁵ Pa, and the remaining deposition conditions were kept the same for each test piece. The reflectance of each of the prepared test pieces was measured.

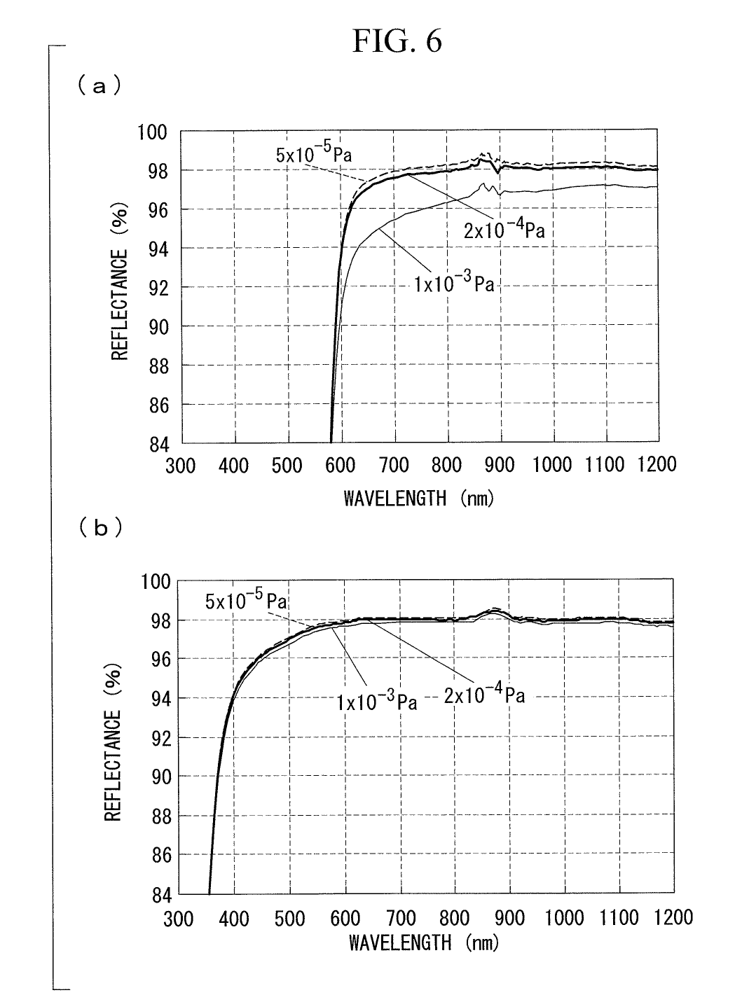

FIG. 6 is a graph illustrating the wavelength dispersion of the light reflectance of the metal thin films upon variation in the ultimate pressure during the evacuation step, wherein (a) illustrates the results for the Cu thin films, and (b) illustrates the results for the Ag thin films. In both figures, the horizontal axis represents the wavelength and the vertical axis represents the reflectance.

The Ag thin films exhibited high reflectance at all of the ultimate pressure values. On the other hand, in the case of the Cu thin films, the reflectance deteriorated once the ultimate pressure exceeded 2×10⁻⁴ Pa. Because Cu oxidizes more readily than Ag, the setting of a favorable ultimate degree of vacuum is necessary. In order to inhibit oxidation of the Cu thin film, the partial pressure ratio of ultimate pressure/Ar gas is preferably not more than 5×10⁻⁴. This enables the amounts of moisture and oxygen within the atmosphere to be reduced to 500 ppm or less. Based on this result, reducing the ultimate pressure to a value of not more than 2×10⁻⁴ Pa better suppresses oxidation of the Cu thin film, enabling the deposition of a Cu thin film having high reflectance.

When the ultimate pressure in the evacuation step was set to not more than 2×10⁻⁴ Pa, the Cu thin film and the Ag thin film both exhibited stable reflectance for wavelengths of 650 nm or greater. In a tandem solar cell, because the wavelength of the light reaching the back electrode layer is 650 nm or greater, this result confirmed that the Cu thin film could be employed within a tandem solar cell.

### (Deposition Temperature)

Cu thin films having a thickness of 200 nm were deposited on glass substrates to prepare a series of test pieces. The deposition was performed using a sputtering apparatus, by performing an evacuation down to an ultimate pressure of not more than 2×10⁻⁴ Pa, subsequently introducing Ar gas as the sputtering gas, and then generating a discharge. During this process, the deposition temperature was set to 100° C., 110° C., 120° C., 170° C., 240° C. or 250° C. The remaining deposition conditions were kept the same for each test piece. The reflectance of each of the prepared test pieces was measured.

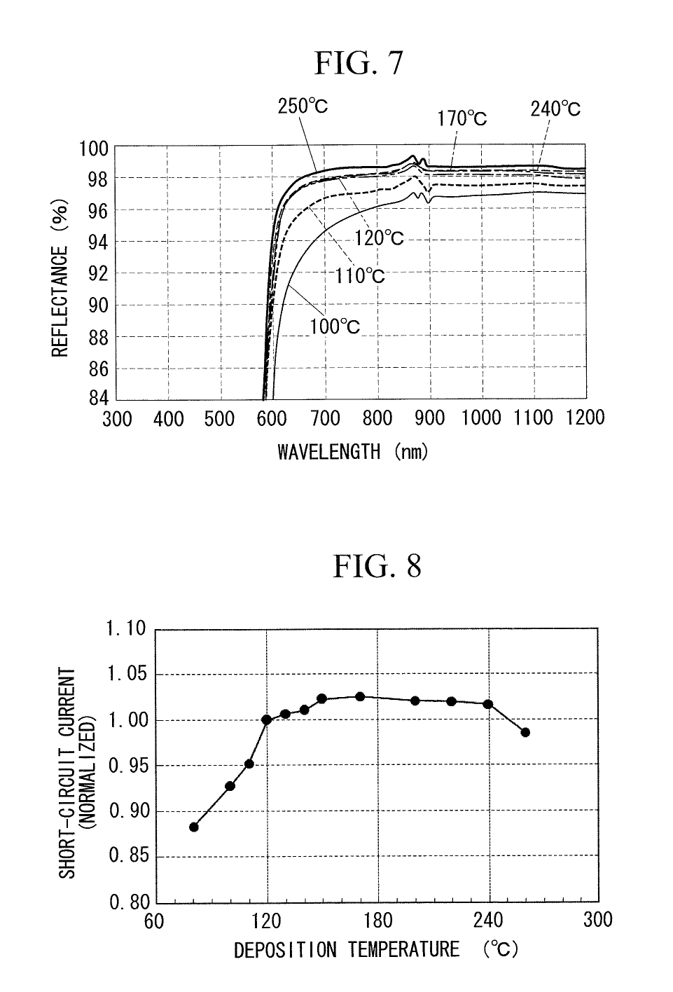

FIG. 7 is a graph illustrating the wavelength dispersion of the reflectance upon variation in the deposition temperature during deposition of the Cu thin film having a thickness of 200 nm. In the figure, the horizontal axis represents the wavelength and the vertical axis represents the reflectance. For wavelengths of 650 nm or greater, setting the deposition temperature to 120° C. or higher enabled deposition of a Cu thin film having a reflectance of not less than 97%.

Tandem solar cell modules were prepared in which the back electrode layer was formed by depositing a Cu thin film in the same manner as that described above, and the performance of these modules was investigated. The structure of the modules is described below.

The transparent electrode layer was a SnO₂ layer with a thickness of 500 nm to 800 nm. In the first cell layer composed of amorphous silicon, the thickness of the p-layer was from 10 nm to 30 nm, the thickness of the i-layer was from 200 nm to 350 nm, and the thickness of the n-layer was from 30 nm to 50 nm. The intermediate contact layer was a GZO film with a thickness of 20 nm to 100 nm. In the second cell layer composed of crystalline silicon, the thickness of the p-layer was from 10 nm to 50 nm, the thickness of the i-layer was from 1.2 μm to 3.0 μm, and the thickness of the n-layer was from 20 nm to 50 nm.

The backside transparent electrode layer was a GZO film with a thickness of 50 nm to 100 nm. The protective film was a Ti film with a thickness of 5 nm to 150 nm.

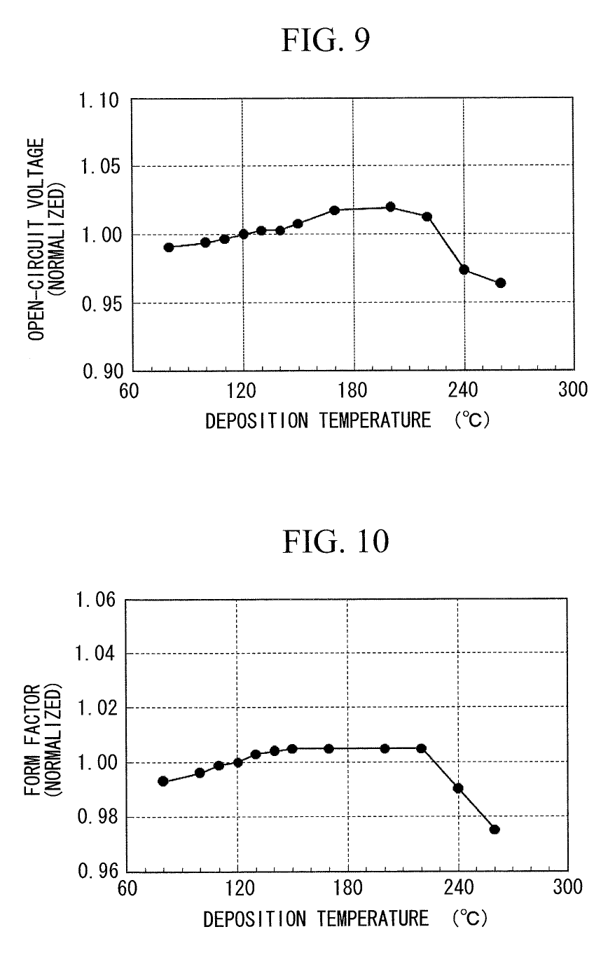

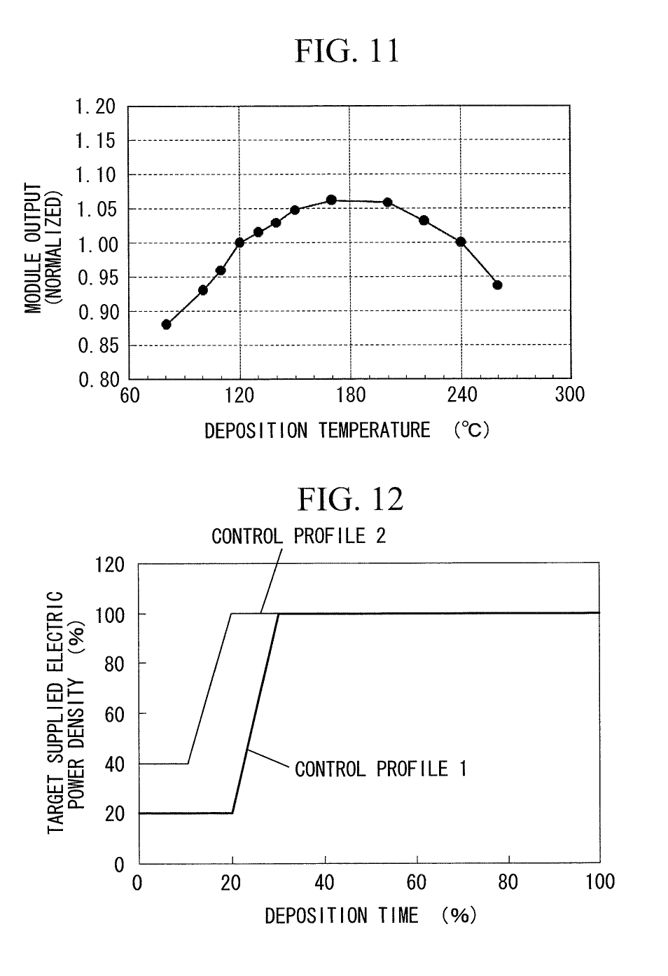

FIG. 8 to FIG. 11 illustrate the variation in the short-circuit current, the open-circuit voltage, the form factor and the module output for the tandem solar cell module when the deposition temperature during the Cu thin film formation step was varied from 80° C. to 260° C. In these figures, the horizontal axis represents the deposition temperature, and the vertical axis represents the normalized value for the short-circuit current, the open-circuit voltage, the form factor and the module output respectively.

As the deposition temperature was increased, the short-circuit current and the open-circuit voltage increased, and the module output and form factor also improved. However, when the deposition temperature exceeded 240° C., the open-circuit voltage decreased markedly, and the module output also decreased. It is thought that these observations are due to diffusion of the doping materials from the p-layer and n-layer of the first cell layer into the i-layer. Further, if the deposition temperature was less than 120° C., then the short-circuit current decreased markedly, and the module output also decreased. It is thought that this observation is due to suppression of atom migration during the Cu deposition, which leads to the generation of large numbers of voids and defects at the crystal grain boundaries within the Cu thin film at the interface with the backside transparent electrode layer, resulting in a significant reduction in the reflectance.

Based on the above results, it is evident that setting the deposition temperature to not less than 120° C. and not more than 240° C. yields superior module efficiency. Because the module output is at a maximum for deposition temperatures from 150° C. to 200° C., setting the deposition temperature to not less than 150° C. and not more than 200° C. yields even better module efficiency.

### (Control Profile for Target Supplied Electric Power Density)

FIG. 12 illustrates examples of control profiles for the target supplied electric power density during the deposition step in the Cu thin film formation step. In this figure, the horizontal axis represents the deposition time (normalized), and the vertical axis represents the target supplied electric power density (normalized). The control profiles comprise an initial stage of applying an initial target supplied electric power density, a transition stage of transitioning from the initial target supplied electric power density to a steady-state target supplied electric power density, and a steady-state stage of maintaining the steady-state target supplied electric power density.

In a control profile 1, the initial target supplied electric power density in the initial stage is set to 20% of the steady-state target supplied electric power density, and is applied for 20% of the total deposition time. In the transition stage, deposition is performed while the initial target supplied electric power density is increased to the steady-state target supplied electric power density over a period of time that represents 10% of the total deposition time.

In a control profile 2, the initial target supplied electric power density in the initial stage is set to 40% of the steady-state target supplied electric power density, and is applied for 10% of the total deposition time. In the transition stage, deposition is performed while the initial target supplied electric power density is increased to the steady-state target supplied electric power density over a period of time that represents 10% of the total deposition time.

Performing the deposition with a constant target supplied electric power density from the start of deposition until the completion of deposition is referred to as “no control”.

Using a sputtering apparatus, Cu thin films and Ag thin films were deposited on glass substrates with different control profiles for the target supplied electric power density, thus preparing a series of test pieces. The reflectance of each test piece was measured. Besides the control profile, the remaining deposition conditions were kept the same for each test piece.

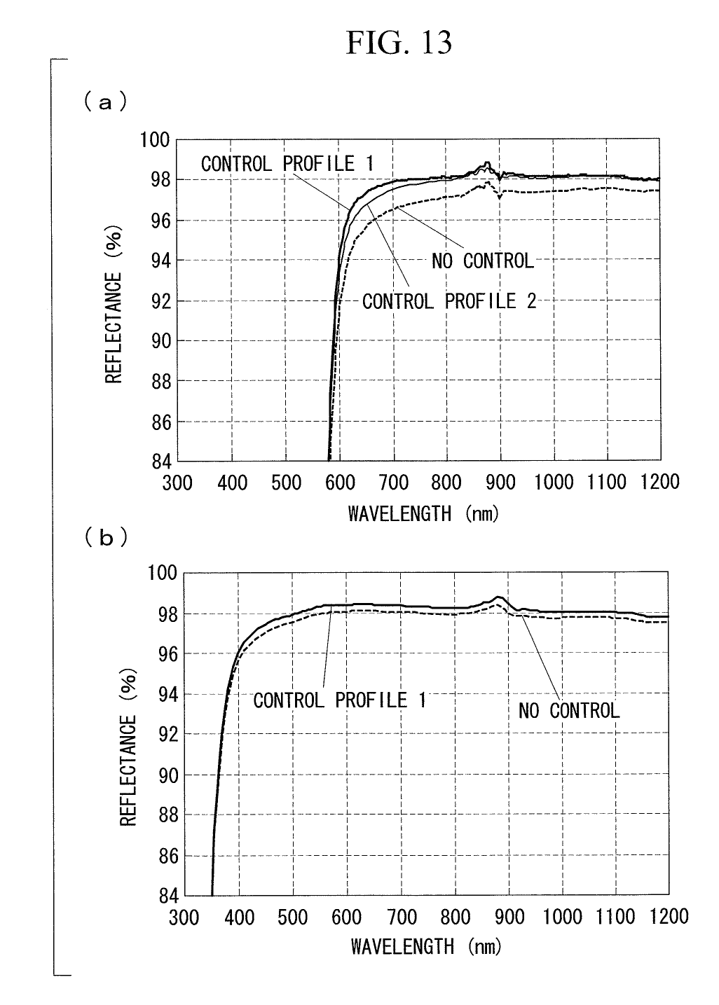

FIG. 13 illustrates the wavelength dispersion of the light reflectance of the metal thin film with and without control of the target supplied electric power density during deposition of the metal thin film, wherein (a) illustrates the results for the Cu thin films, and (b) illustrates the results for the Ag thin films. In both figures, the horizontal axis represents the wavelength and the vertical axis represents the reflectance. For the test pieces in which an Ag thin film was deposited, a high reflectance was obtained regardless of whether or not the target supplied electric power density was controlled. On the other hand, for the test pieces in which a Cu thin film was deposited, the reflectance decreased if the target supplied electric power density was not controlled. This result confirmed that because Cu oxidizes more readily than Ag, controlling the target supplied electric power density is necessary to suppress oxidation.

For the test pieces in which a Cu thin film was deposited, the control profile 1 yielded superior light reflectance to the control profile 2. This is because the target supplied electric power density in the initial stage of the deposition step was lower and the application time was longer in the control profile 1, meaning damage to the interface between the backside transparent electrode layer and the Cu thin film was minimized, and oxidation was suppressed. When a Cu thin film is stacked on a backside transparent electrode layer comprising mainly a metal oxide, the Cu thin film is prone to oxidation at the interface, but the above results confirmed that oxidation of the Cu thin film at the interface was able to be suppressed.

### (Effect of the Thickness of the Cu Thin Film)

Cu thin films of various thicknesses were deposited on glass substrates to prepare a series of test pieces. The deposition was performed using a sputtering apparatus, by performing an evacuation down to an ultimate pressure of not more than 2×10⁻⁴ Pa, subsequently introducing Ar gas as the sputtering gas, and then generating a discharge. The thickness of the Cu thin film was set to 80 nm, 100 nm, 200 nm, 400 nm or 450 nm. The light reflectance of each of the prepared test pieces was measured.

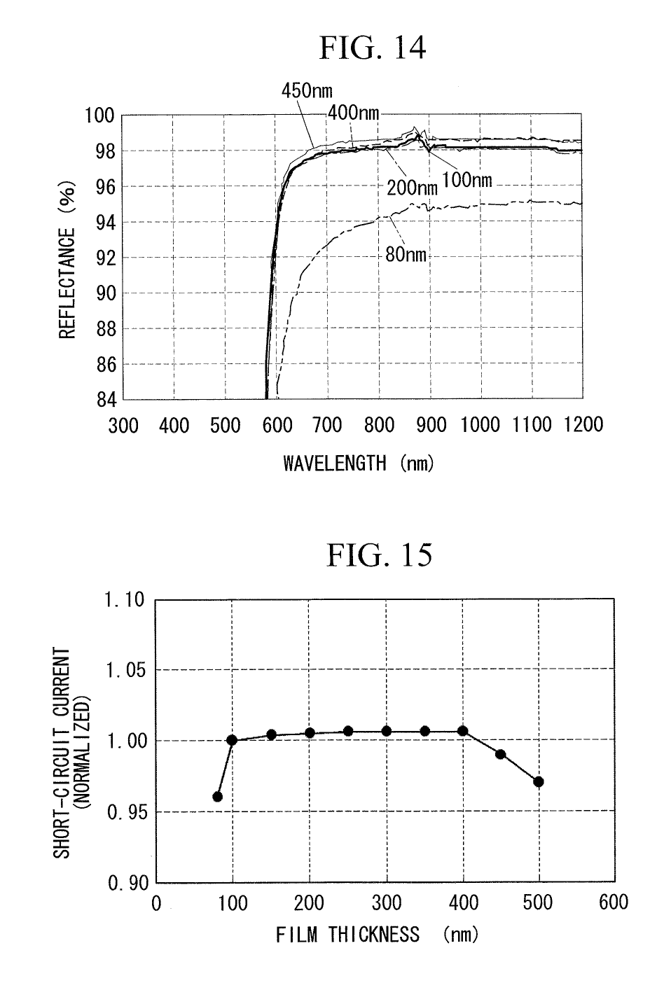

FIG. 14 illustrates the wavelength dispersion of the light reflectance upon variation in the Cu thin film thickness. In the figure, the horizontal axis represents the wavelength and the vertical axis represents the reflectance. When the thickness was at least 100 nm, a high reflectance was achieved. Although not shown in the figure, in the case of an Ag thin film, a high reflectance could not be achieved unless the thickness was at least 200 nm.

Tandem solar cell modules were prepared in which the back electrode layer was formed by depositing a Cu thin film in the same manner as that described above, and the performance of the modules was investigated. The structure of the modules was the same as that described above when investigating the deposition temperature.

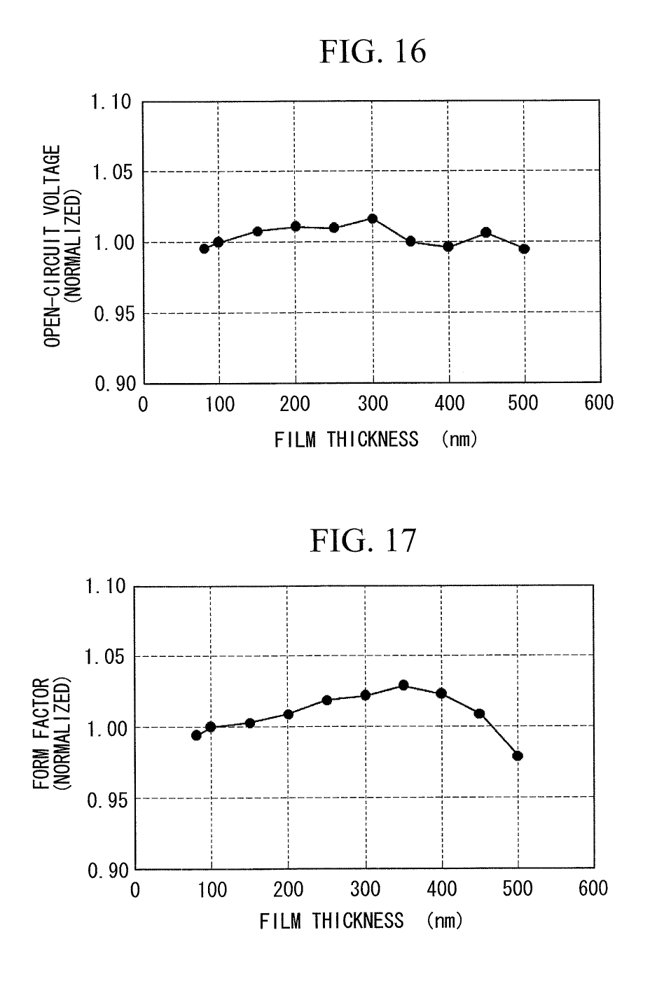

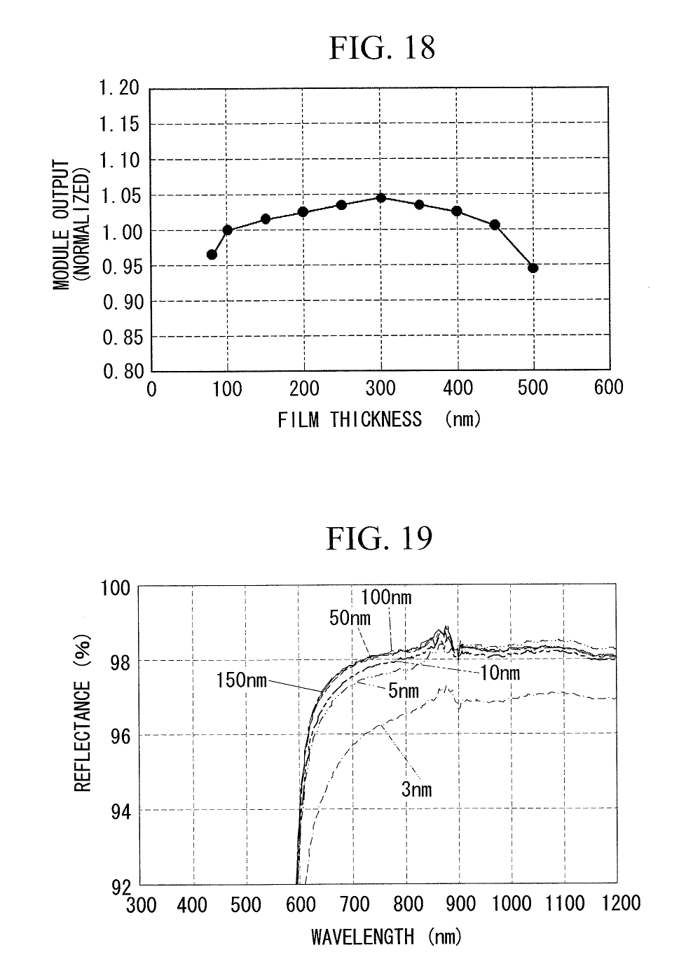

FIG. 15 to FIG. 18 illustrate the variation in the short-circuit current, the open-circuit voltage, the form factor and the module output for the tandem solar cell module when the Cu thin film thickness was varied. In these figures, the horizontal axis represents the Cu thin film thickness, and the vertical axis represents the normalized value for the short-circuit current, the open-circuit voltage, the form factor and the module output respectively. As the Cu thin film thickness was increased, the short-circuit current and the open-circuit voltage increased, and the module output and form factor also improved. However, when the Cu thin film thickness exceeded 450 nm, the processing precision of the laser etching tended to deteriorate, and therefore the form factor decreased. Based on the above results, it is evident that setting the Cu thin film thickness to not less than 100 nm and not more than 450 nm yields superior module efficiency.

### (Confirmation of Laser Processing Conditions)

Using the test pieces described above, the generation of burrs during laser etching was observed. When the pulse oscillation during laser etching was set to 13 kHz, the optimal range for the laser power was from 0.24 W to 0.26 W in the case of a back electrode layer comprising Ag. In comparison, the optimal range was from 0.20 W to 0.30 W in the case of a back electrode layer comprising a Cu thin film. Accordingly, when a back electrode layer comprising a Cu thin film was subjected to laser etching, no burr generation occurred, and processing was able to be performed in a stable manner. The above results revealed that the optimal range for the laser processing conditions was broader than that observed for Ag thin films, meaning a high level of robustness could be achieved relative to fluctuations in the laser power or the like.

### (Protective Film)

Using a sputtering apparatus, Cu thin films were deposited on glass substrates, and a film of Ti was then stacked on the Cu thin film inside the same chamber to prepare a series of test pieces. The reflectance when light was irradiated from the substrate side of the structure was measured for each test piece. The ultimate pressure was set to 2×10⁻⁴ Pa and the deposition temperature was set to 200° C. The thickness of the Ti film was 3 nm, 5 nm, 10 nm, 50 nm, 100 nm or 150 nm. The reflectance was measured in accordance with JIS R 3106. A white board was used as a standard sample.

FIG. 19 illustrates the wavelength dispersion of the light reflectance of the Cu thin film/Ti film test pieces following thermal annealing at 200° C. for 45 minutes in an open atmosphere upon variation in the Ti film thickness. When the film thickness was 3 nm, the reflectance decreased. When the film thickness exceeded 50 nm, the stability of the adhesion to the Cu thin film deteriorated, and the probability of detachment under stress increased to 1% of the produced structures. Moreover, when the film thickness exceeded 150 nm, detachment occurred with a probability of 5%. The above results confirmed that by using a Ti film as a protective film for preventing corrosion of the Cu thin film, and setting the thickness of the Ti film to not less than 5 nm and not more than 150 nm, a high reflectance could be achieved for the Cu thin film with minimal chance of detachment.

### REFERENCE SIGNS LIST

1 Substrate
2 Transparent electrode layer
3 Photovoltaic layer
4 Back electrode layer
5 Intermediate contact layer
6 Solar cell module
10, 12 Slot
11 Connection slot
14 Peripheral film removed region
15 Insulation slot
23 Terminal box
24 Backing sheet
31 Amorphous silicon p-layer
32 Amorphous silicon i-layer
33 Amorphous silicon n-layer
41 Crystalline silicon p-layer
42 Crystalline silicon i-layer
43 Crystalline silicon n-layer
50 Solar cell panel
51 Backside transparent electrode layer
52 Cu thin film
91 First cell layer
92 Second cell layer
100 Photovoltaic device (tandem silicon-based solar cell)

1. A process for producing a photovoltaic device, the process comprising forming two photovoltaic layers and a back electrode layer on a substrate, wherein
formation of the back electrode layer comprises a backside transparent electrode layer formation step and a Cu thin film formation step,
the Cu thin film formation step comprises, in sequence, an evacuation step and a deposition step,
an ultimate pressure reached in the evacuation step is not more than 2×10 Pa, and
a temperature in the deposition step is not less than 120° C. and not more than 240° C.

2. The process for producing a photovoltaic device according to claim 1, wherein
the deposition step comprises an initial stage of applying an initial target supplied electric power density, and a steady-state stage of maintaining a steady-state target supplied electric power density, and
the initial target supplied electric power density is not less than 10% and not more than 50% of the steady-state target supplied electric power density.

3. The process for producing a photovoltaic device according to claim 2, wherein
a time for which the initial target supplied electric power density is applied is not less than 10% and not more than 30% of a total deposition time.

4. The process for producing a photovoltaic device according to claim 1, wherein
the deposition step comprises a transition stage for transitioning from an initial target supplied electric power density to a steady-state target supplied electric power density, and
a transition time for the transition stage is not less than 5% and not more than 10% of a total deposition time.

5. The process for producing a photovoltaic device according to claim 1, wherein the back electrode layer comprises a protective film.
